(19) United States
(12) Patent Application Publication
(10) Pub. No.: US 2014/0048401 A1
(43) Pub. Date: Feb. 20, 2014

(54) TRANSPARENT CONDUCTIVE LAMINATE, METHOD FOR MANUFACTURING THE SAME AND CAPACITANCE TYPE TOUCH PANEL

(71) Applicant: Toppan Printing Co., Ltd., Tokyo (JP)

(72) Inventor: Hiroshi Kobayashi, Tokyo (JP)

(73) Assignee: Toppan Printing Co., Ltd., Tokyo (JP)

(21) Appl. No.: 13/766,631

(22) Filed: Feb. 13, 2013

Related U.S. Application Data
(63) Continuation of application No. 13/040,196, filed on Mar. 3, 2011, now abandoned.
Application No. 13/040,196 is a continuation of application No. PCT/JP2010/053916, filed on Mar. 9, 2010.

(30) Foreign Application Priority Data
Nov. 27, 2009 (JP) 2009-269880

(51) Int. Cl. H03K 17/96

(52) U.S. Cl. CPC H03K 17/962
USPC 200/600; 174/250

(57) ABSTRACT

One embodiment of the present invention is a transparent conductive laminate including a transparent substrate layer, a first transparent conductive layer and a second transparent conductive layer formed on both surfaces of the transparent substrate layer, a first conductive pattern area and a first nonconductive pattern area formed on the first transparent conductive layer, and a second conductive pattern area and a second nonconductive pattern area formed on the second transparent conductive layer, wherein at least one layer formed between the first transparent conductive layer and the second transparent conductive layer is a layer including an ultraviolet absorbing agent or a resin in which a non-reactive ultraviolet absorbing agent to which at least one functional group selected from a vinyl group, an acryloyl group, a methacryloyl group, an alcoholic hydroxyl group, an amino group, a carboxyl group, an epoxide group and an isocyanate group is added is copolymerized.

This application is a continuation of application Ser. No. 13/040,196, filed on Mar. 3, 2011, which is a continuation of International Application No. PCT/JP2010/053916, filed on Mar. 9, 2010, and the entire contents of both are incorporated herein by reference.

### BACKGROUND OF THE INVENTION

### Field of the Invention

The present invention related to a transparent conductive laminate and a method for manufacturing the transparent conductive laminate.

In recent years, a transparent touch panel is arranged on various displays of electronics devices as an input device. As a type of a touch panel, a resistance film type and a capacitance type can be exemplified. In particular, the capacitance type can receive a multi-touch and is widely employed for uses such as mobile devices.

The capacitance type touch panel uses a transparent conductive layer having a pattern. As a method for forming a pattern of the transparent conductive layer, for example, photolithography in which a resist is used for patterning can be used as shown in patent documents 1-3. As another method, a method in which a pattern exposure is carried out using an indium compound having a functional group or part which is reactive to light, or a tin compound having the similar functional group or part as a composition for forming a conductive film can be used as in patent document 4. A method in which a pattern is formed with a laser can be used as in patent document 5.

Since the capacitance type touch panel is used on a display, when a pattern shape of the transparent conductive layer is prominent, visibility is reduced. Thus, in order to not decrease an image quality of the display, a transparent conductive laminate for a touch panel with a high transparency has been suggested by forming an optical adjustment layer other than a transparent conductive layer as in patent document 6.

However, the photolithography as in Patent Documents 1-3 requires a large number of manufacturing steps in many cases. In particular, when patterns are formed by arranging the transparent conductive layers on both surfaces of a substrate, a manufacturing step becomes cumbersome, because a manufacturing step, for example, application, exposure and development of a resist are carried out for each of the surfaces of the substrate. In addition, when an optical adjustment layer is formed other than a transparent conductive layer in order to solve the issue of reduction in visibility as in Patent Document 6, the number of manufacturing step are inevitably increased and therefore, the manufacturing steps further become cumbersome.

In the methods disclosed by Patent Documents 4 and 5, the number of manufacturing steps can be reduced without using a resist. However, in the method of Patent Document 4, a position adjustment of the patterns formed on both surfaces of a substrate becomes difficult when the patterns are formed by arranging transparent conductive layers on both surfaces of the substrate. In particular, when forming fine patterns on both surfaces of the substrate, a position adjustment of the patterns is important. On the other hand, in the method of Patent Document 5, the same patterns can be formed on both surfaces of a substrate using a laser beam. However, the method cannot be applied when different patterns are formed on both surfaces of the substrate.

The present invention is conceived to address these conventional problems. One object of the present invention is to provide a transparent conductive laminate, a method for manufacturing thereof and a capacitance type touch panel in which patterns having different shapes can be simultaneously formed on both surfaces of a substrate with a short manufacturing process even when a method for forming the patterns on a transparent conductive layer using a resist is used, and a position adjustment can be easily carried out even when the patterns on both surfaces of the substrate are fine, and further with the advantage that the shapes of the patterns can formed to be less prominent.
Patent Document 1: JP-A-H01-197911
Patent Document 2: JP-A-H02-109205
Patent Document 3: JP-A-H02-309510
Patent Document 4: JP-A-H09-142884
Patent Document 5: JP-A-2008-140130
Patent Document 6: JP-A-H11-286066

### SUMMARY OF THE INVENTION

A first aspect of the present invention is a transparent conductive laminate including a transparent substrate layer, a first transparent conductive layer and a second transparent conductive layer formed on both surfaces of the transparent substrate layer, a first conductive pattern area and a first nonconductive pattern area formed on the first transparent conductive layer, and a second conductive pattern area and a second nonconductive pattern area formed on the second transparent conductive layer, wherein at least one layer formed between the first transparent conductive layer and the second transparent conductive layer is a layer including an ultraviolet absorbing agent or a resin in which a non-reactive ultraviolet absorbing agent to which at least one functional group selected from a vinyl group, an acryloyl group, a methacryloyl group, an alcoholic hydroxyl group, an amino group, a carboxyl group, an epoxide group and an isocyanate group is added is copolymerized.

A second aspect of the present invention is the transparent conductive laminate according to the first aspect, wherein the transparent substrate layer includes an ultraviolet absorbing agent or a resin in which a non-reactive ultraviolet absorbing agent to which at least one functional group selected from a vinyl group, an acryloyl group, a methacryloyl group, an alcoholic hydroxyl group, an amino group, a carboxyl group, an epoxide group and an isocyanate group is added is copolymerized.

A third aspect of the present invention is the transparent conductive laminate according to the first aspect, further including a resin layer formed between the transparent substrate layer and the first transparent conductive layer and/or between the transparent substrate layer and the second transparent conductive layer, wherein the resin layer includes an ultraviolet absorbing agent or a resin in which a non-reactive ultraviolet absorbing agent to which at least one functional group selected from a vinyl group, an acryloyl group, a methacryloyl group, an alcoholic hydroxyl group, an amino group, a carboxyl group, an epoxide group and an isocyanate group is added is copolymerized.

A fourth aspect of the present invention is the transparent conductive laminate according to the first aspect, wherein the transparent substrate layer comprises a first transparent substrate layer having a first surface and a second surface, a second transparent substrate layer having a first surface and a second surface, and an adhesive layer, wherein the first transparent conductive layer is formed on the first surface of the first transparent substrate layer, the second transparent conductive layer is formed on the first surface of the second transparent substrate layer, the adhesive layer is formed between the second surface of the first transparent substrate layer and the second surface of the second transparent substrate layer,

wherein

the adhesive layer includes an ultraviolet absorbing agent or a resin in which a non-reactive ultraviolet absorbing agent to which at least one functional group selected from a vinyl group, an acryloyl group, a methacryloyl group, an alcoholic hydroxyl group, an amino group, a carboxyl group, an epoxide group and an isocyanate group is added is copolymerized.

A fifth aspect of the present invention is the transparent conductive laminate according to the first aspect, further including an optical adjustment layer formed between the transparent substrate layer and the first transparent conductive layer and/or between the transparent substrate layer and the second transparent conductive layer.

A sixth aspect of the present invention is the transparent conductive laminate according to the fifth aspect, wherein the transparent conductive laminate exhibits a light transmittance for a wavelength of 400 nm is equal to or more than 60% and a light transmittance for a wavelength of 365 nm is equal to or less than 20%.

A seventh aspect of the present invention is the transparent conductive laminate according to the sixth aspect, wherein a gap between an entire light transmittance of the first conductive pattern area and an entire light transmittance of the first nonconductive pattern area is at most 1.5% and a gap between a transmission hue b* of the first conductive pattern area and a transmission hue b* of the first nonconductive pattern area is at most 2.0, and

wherein a gap between an entire light transmittance of the second conductive pattern area and an entire light transmittance of the second nonconductive pattern area is at most 1.5% and a gap between a transmission hue b* of the second conductive pattern area and a transmission hue b* of the second nonconductive pattern area is at most 2.0.

An eighth aspect of the present invention is the transparent conductive laminate according to the seventh aspect, wherein the transparent conductive laminate exhibits a thermal shrinkage rate at 150 degrees Celsius for 30 minutes is at most 0.5%.

A ninth aspect of the present invention is a capacitance type touch panel using the transparent conductive laminate according to the eighth aspect as an electrode material.

A tenth aspect of the present invention is a method for manufacturing a transparent conductive laminate, the method including forming at least a first transparent conductive layer and a second transparent conductive layer on both surfaces of a transparent substrate layer;

applying a resist to surfaces of the first transparent conductive layer and the second transparent conductive layer;

arranging a first optical source, a first optical filter for cutting light and a first mask for forming a pattern in the first transparent conductive layer in said order from a side of the first optical source;

arranging a second optical source, a second optical filter for cutting light and a second mask for forming a pattern in the second transparent conductive layer in said order from a side of the second optical source;

simultaneously exposing the resist applied to the surfaces of the first transparent conductive layer and the second transparent conductive layer;

developing the exposed resist;

etching portions of the first transparent conducive layer and the second transparent conductive layer which are not covered by the resist; and

detaching the resist,

wherein

at least one layer formed between the first transparent conductive layer and the second transparent conductive layer is a layer which absorbs light.

An eleventh aspect of the present invention is the method for manufacturing the transparent conductive laminate according to the tenth aspect, wherein the transparent substrate layer is the layer which absorbs light and the transparent substrate layer includes an ultraviolet absorbing agent or a resin having an ultraviolet absorbing function.

A twelfth aspect of the method for manufacturing the transparent conductive laminate according to the eleventh aspect, wherein each of the first and second optical filters has a light transmittance of at least 80% for a wavelength of 365 nm.

A thirteenth aspect of the present invention is the method for manufacturing the transparent conductive laminate according to the twelfth aspect, wherein a roll to roll method is used from the forming step to the detaching step.

A fourteenth aspect of the present invention is the method for manufacturing the transparent conductive laminate according to the tenth aspect, further including, forming resin layers on both surfaces of the transparent substrate layer, and forming the first transparent conductive layer and the second transparent conductive layer on surfaces of the resin layers, wherein the resin layers are the layers which absorb light and the resin layers include an ultraviolet absorbing agent or a resin having an ultraviolet absorbing function.

A fifteen aspect of the present invention is the method for manufacturing the transparent conductive laminate according to the fourteenth aspect, wherein each of the first and second optical filters has a light transmittance of at least 80% for a wavelength of 365 nm.

A sixteenth aspect of the present invention is the method for manufacturing the transparent conductive laminate according to the fifteenth aspect, wherein a roll to roll method is used from the forming step to the detaching step.

A seventeenth aspect of the present invention is a method for manufacturing a transparent conductive laminate, the method including, forming at least a first transparent conductive layer on one surface of a first transparent substrate layer;

forming at least a second transparent conducive layer on one surface of a second transparent substrate layer;

adhering the first transparent substrate layer and the second transparent substrate layer together with an adhesive layer between the first transparent conductive layer and the second transparent conductive layer;

applying a resist to surfaces of the first transparent conductive layer and the second transparent conductive layer;

arranging a first optical source, a first optical filter for cutting light and a first mask for forming a pattern in the first transparent conductive layer in said order from a side of the first optical source;

arranging a second optical source, a second optical filter for cutting light and a second mask for forming a pattern in the second transparent conductive layer in said order from a side of the second optical source;

simultaneously exposing the resist applied to the surfaces of the first transparent conductive layer and the second transparent conductive layer;

developing the exposed resist;

etching portions of the first transparent conducive layer and the second transparent conductive layer which are not covered by the resist; and

detaching the resist,

wherein

at least one layer formed between the first transparent conductive layer and the second transparent conductive layer is a layer which absorbs light.

An eighteenth aspect of the present invention is the method for manufacturing a transparent conductive laminate according to the seventeenth aspect, wherein the adhesive layer is the layer which absorbs light and the adhesive layer includes an ultraviolet absorbing agent or a resin having an ultraviolet absorbing function.

A nineteenth aspect of the present invention is the method for manufacturing a transparent conductive laminate according to the eighteenth aspect, wherein each of the first and second optical filters has a light transmittance of at least 80% for a wavelength of 365 nm.

### BRIEF DESCRIPTION OF THE DRAWINGS

FIG. 1 is an explanatory diagram of a cross sectional example 1 of a transparent conductive laminate in accordance with an embodiment of the present invention.

FIG. 2 is an explanatory diagram of a cross sectional example 2 of a transparent conductive laminate in accordance with an embodiment of the present invention.

FIG. 3 is an explanatory diagram of a cross sectional example 3 of a transparent conductive laminate in accordance with an embodiment of the present invention.

FIG. 4 is an explanatory diagram of a cross sectional example 4 of a transparent conductive laminate in accordance with an embodiment of the present invention.

FIG. 5 is an explanatory diagram of a cross sectional example 5 of a transparent conductive laminate in accordance with an embodiment of the present invention.

FIG. 6 is an explanatory diagram of a cross sectional example 6 of a transparent conductive laminate in accordance with an embodiment of the present invention.

FIG. 7 is an explanatory diagram of a cross sectional example 7 of a transparent conductive laminate in accordance with an embodiment of the present invention.

FIG. 8 is an explanatory diagram of a cross sectional example 8 of a transparent conductive laminate in accordance with an embodiment of the present invention.

FIG. 9 is an explanatory diagram of a pattern example (an X coordinate) of a transparent conductive layer.

FIG. 10 is an explanatory diagram of a pattern example (a Y coordinate) of a transparent conductive layer.

FIG. 11 is an explanatory diagram of a positional relationship between an X coordinate and a Y coordinate of a pattern example of a transparent conductive layer.

FIG. 12 is an explanatory diagram of an example of an exposure process of a transparent conductive laminate in accordance with an embodiment of the present invention.

FIGS. 13A-G are explanatory diagrams of an example showing pattern-formation processes of a transparent conductive laminate in accordance with an embodiment of the present invention.

### DETAILED DESCRIPTION OF THE INVENTION

The embodiments of the present invention are explained as follows using the diagrams. The present invention is not limited to the following embodiments and modifications such as a design choice can be added based on the knowledge of one of ordinary skill in the art. The embodiments including such modifications are included in the present invention.

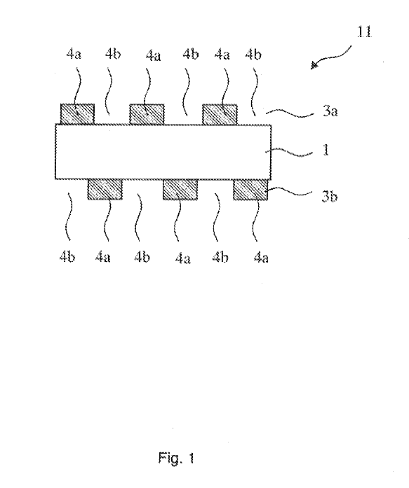

FIG. 1 is an explanatory diagram of a cross sectional example 1 of a transparent conductive laminate in accordance with an embodiment of the present invention. A transparent conductive laminate 11 comprises a first transparent conductive layer 3a and a second transparent conductive layer 3b formed on both surfaces of a transparent substrate 1. The first transparent conductive layer 3a has a conductive pattern area 4a and a nonconductive pattern area 4b, and the second transparent conductive layer 3b has a conductive pattern area 4a and a nonconductive pattern area 4b. Here, the conductive pattern area is a part having an electrical conductivity among the transparent conductive layers and the nonconductive pattern area is a part which does not have an electrical conductivity among the transparent conductive layers, excluding the part having electrical conductivity.

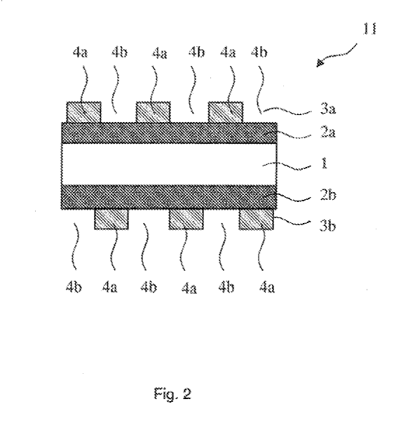

FIG. 2 is an explanatory diagram of a cross sectional example 2 of a transparent conductive laminate in accordance with an embodiment of the present invention. As shown in FIG. 2, optical adjustment layers 2a and 2b may be respectively formed between the transparent substrate 1 and the first transparent conductive layer 3a, and between the transparent substrate 1 and the second transparent conductive layer 3b of the transparent conductive laminate 11 of FIG. 1. As another embodiment, an optical adjustment layer may be formed either between the transparent substrate 1 and the first transparent conductive layer 3a or between the transparent substrate 1 and the second transparent conductive layer 3b.

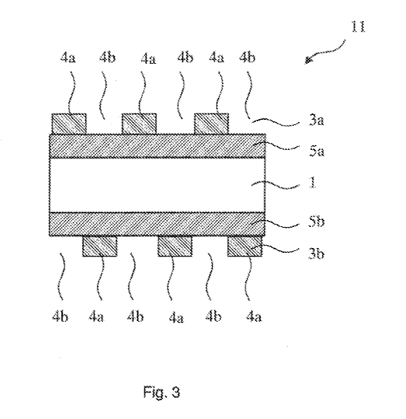

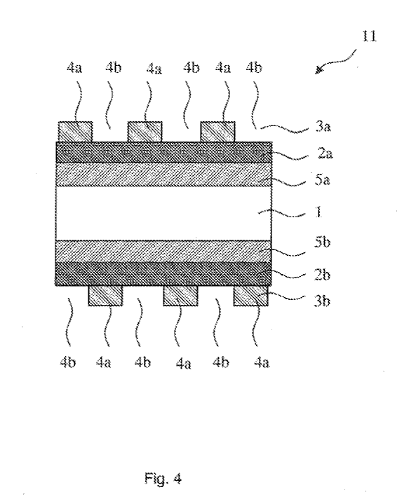

FIG. 3 is an explanatory diagram of a cross sectional example 3 of a transparent conductive laminate in accordance with an embodiment of the present invention. The transparent conductive laminate 11 includes the first transparent conductive layer 3a and the second transparent conductive layer 3b which are formed on both surfaces of the transparent substrate 1, and resin layers 5a and 5b. The first transparent conductive layer 3a has the conductive pattern area 4a and the nonconductive pattern area 4b, and the second transparent conductive layer 3b has the conductive pattern area 4a and the nonconductive pattern area 4b. The resin layers 5a and 5b are respectively formed between the transparent substrate 1 and the first transparent conductive layer 3a and between the transparent substrate 1 and the second transparent conductive layer 3b. As another embodiment, a resin layer may be formed either between the transparent substrate 1 and the first transparent conductive layer 3a or between the transparent substrate 1 and the second transparent conductive layer 3b.

FIG. 4 is an explanatory diagram of a cross sectional example 4 of a transparent conductive laminate in accordance with an embodiment of the present invention. As shown in FIG. 4, optical adjustment layers 2a and 2b may be respectively formed between the resin layer 5a and the first transparent conductive layer 3a, and between the resin layer 5b and the second transparent conductive layer 3b of the transparent conductive laminate 11 of FIG. 3. As another embodiment, an optical adjustment layer may be formed either between the resin layer 5a and the first transparent conductive layer 3a or between the resin layer 5b and the second transparent conductive layer 3b. In addition, an optical adjustment layer may be formed between the transparent substrate 1 and the resin layer 5a or between the transparent substrate 1 and the resin layer 5b.

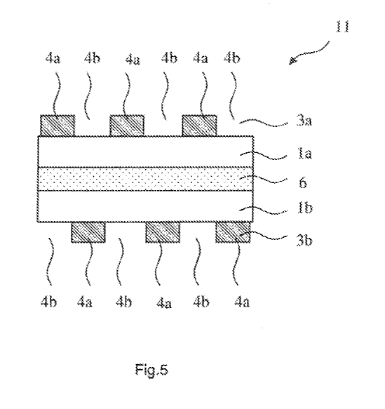

FIG. 5 is an explanatory diagram of a cross sectional example 5 of a transparent conductive laminate in accordance with an embodiment of the present invention. The transparent conductive laminate 11 includes a first transparent conductive layer 3a formed on one surface of a first transparent substrate 1a, a second transparent conductive layer 3b formed on one surface of a second transparent substrate 1b and an adhesive layer 6. The first transparent conductive layer 3a has a conductive pattern area 4a and a nonconductive pattern area 4b, and the second transparent conductive layer 3b has a conductive pattern area 4a and a nonconductive pattern area 4b. The adhesive layer 6 is arranged between the first transparent substrate 1a and the second transparent substrate 1b such that the first transparent conductive layer 3a and the second transparent conductive layer 3b are located outside.

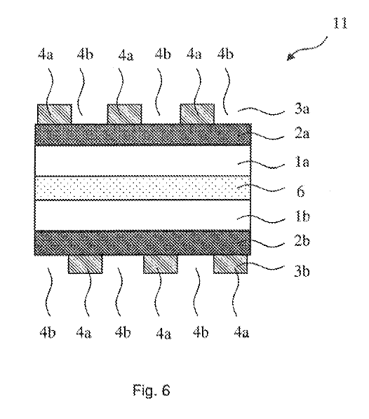

FIG. 6 is an explanatory diagram of a cross sectional example 6 of a transparent conductive laminate in accordance with an embodiment of the present, invention. As shown in FIG. 6, optical adjustment layers 2a and 2b may be respectively formed between the first transparent substrate 1a and the first transparent conductive layer 3a and between the second substrate 1b and the second transparent conductive layer 3b of the transparent conductive laminate 11 of FIG. 5. As another embodiment, an optical adjustment layer may be formed either between the first transparent substrate 1a and the first transparent conductive layer 3a or between the second transparent substrate 1b and the second transparent conductive layer 3b.

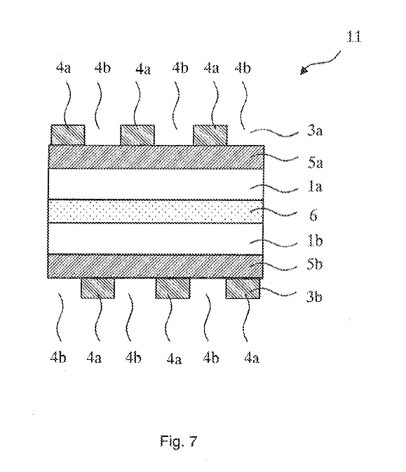

FIG. 7 is an explanatory diagram of a cross sectional example 7 of a transparent conductive laminate in accordance with an embodiment of the present invention. In the transparent conductive laminate 11, the resin layers 5a and 5b may be respectively formed between the first transparent substrate 1a and the first transparent conductive layer 3a, and between the second transparent substrate 1b and the second transparent conductive layer 3b. As another embodiment, a resin layer may be formed either between the first transparent substrate 1a and the first transparent conductive layer 3a or between the second transparent substrate 1b and the second transparent conductive layer 3b.

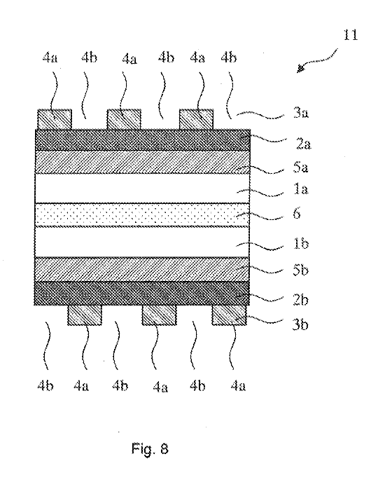

FIG. 8 is an explanatory diagram of a cross sectional example 8 of a transparent conductive laminate in accordance with an embodiment of the present invention. As shown in FIG. 8, optical adjustment layers 2a and 2b may be respectively formed between the resin layer 5a and the first transparent conductive layer 3a and between the resin layer 5b and the second transparent conductive layer 3b of the transparent conductive laminate 11 of FIG. 7. As another embodiment, an optical adjustment layer may be formed either between the resin layer 5a and the first transparent conductive layer 3a, or between the resin layer 5b and the second transparent conductive layer 3b. In addition, an optical adjustment layer may be formed between the first transparent substrate 1a and the resin layer 5a or between the second transparent substrate 1b and the resin layer 5b.

In addition to glass, a plastic film made of a resin can be used for the transparent substrate layers 1, 1a and 1b. The plastic film is not limited as long as the film has sufficient strength and excellent surface flatness during a film-formation process and a post process. For example, a polyethylene terephthalate film, a polybutylene terephthalate film, a polyethylene naphthalate film, a polycarbonate film, a polyethersulfone film, a polysulfone film, a polyarylate film, a cyclic polyolefin film or a polyimide film can be used. A film thickness of approximately at least 10 μm and at most 200 μm can be used while considering thinness and flexibility of a component and base material respectively.

The transparent substrate layers 1, 1a and 1b used in the present invention preferably absorb light. This is because if the transparent substrate layer can absorb light, when patterns are formed on the transparent conductive layers on both surfaces of the transparent substrate layer 1. the transparent substrate layer 1 is able to absorb light which is not absorbed into the resist among the light with which one surface of the transparent substrate layer 1 is irradiated, and this can prevent the light from reaching the resist in a side of the other surface of the transparent substrate layer 1. In particular, when different patterns are simultaneously formed on both surfaces of the transparent substrate layer 1, an overlapping of a pattern on one surface and a pattern on the other surface can be prevented, because a resist on one surface only can be exposed. The transparent substrate layers 1a and 1b preferably absorb light for the same reason.

As mentioned above, the transparent substrate layers 1, 1a and 1b preferably absorb light for exposing a resist. The light for exposing the resist differs depending on the type of a resist or the type of optical source. Since light having a wavelength of an ultraviolet region (approximately 200 nm-360 nm) and light having a wavelength of a visible region (approximately 360 nm-780 nm) are mostly used, the transparent substrate layer 1 preferably absorbs light having these wavelengths. Particularly, the transparent substrate layer 1 more preferably absorbs light of the ultraviolet region in consideration of practicability.

As a light absorbing material for absorbing ultraviolet light, an ultraviolet absorbing agent or a resin having an ultraviolet absorbing function can be exemplified. In addition, the ultraviolet absorbing agent can be added to the transparent substrate layer or a resin for forming the transparent substrate layer and a resin having the ultraviolet absorbing function can be copolymerized.

As an ultraviolet absorbing agent included in the transparent substrate layers 1, 1a and 1b, benzophenone series, benzotriazole series, benzoate series, salicylate series, triazine series, cyanoacrylate series or the like can be exemplified. Particularly, for example, as an ultraviolet absorbing agent of benzotriazole series, 2-(2H-benzotriazole-2-yl)-p-cresol, 2-(2H-benzotriazole-2-yl)-4-6-bis(1-methyl-1-phenylethyl)phenol, 2-[5-Chloro(2H)-benzotriazole-2-yl]-4-methyl-6-(tert-butyl), 2-(2H-benzotriazole-4,6-di-tert-pentylphenol, 2-(2H-benzotriazole-2-yl)-4-(1,1,3,3-tetramethylbutyl)phenol or the like, a mixture, a modified product, a polymeric substance and a derivative thereof can be used.

In addition, for example, as an ultraviolet absorbing agent of triazine series, 2-(4,6-diphenyl-1,3,5-triazine-2-yl)-5-[(hexyl)oxy]-phenol, 2-[4-[(2-hydroxy-3-dodecyloxypropyl)oxy]-2-hydroxyphenyl]-4,6-bis(2,4-dimethylphenyl) -1,3,5-triazine, 2-[4-[(2-hydroxy-3-tridecyloxypropyl)oxy]-2-hydroxyphenyl]-4,6-bis(2,4dimethylphenyl) -1,3,5-triazine, 2,4-bis(2,4-dimethylphenyl)-6)-(2-hydroxy-4-iso-octyloxyphenyl)-s-triazine or the like, a mixture, a modified product, a polymeric substance or a derivative thereof can be used. These materials may be used as a single material or as a mixed material in which these materials are mixed.

Furthermore, as a resin having an ultraviolet absorbing function, a material in which a functional group having a polymerizable double bond such as a vinyl group, an acryloyl group, a methacryloyl group or the like, an alcoholic hydroxyl group, an amino group, a carboxyl group, an epoxide group, an isocyanate group or the like is added to a non-reactive ultraviolet absorbing agent of the above described benzophenone series, benzotriazole series, benzoate series, salicylate series, triazine series, cyanoacrylate series or the like can be used. A transparent substrate layer having an ultraviolet absorbing function can be used by copolymerizing the above resin and the resin included in the transparent substrate layers 1, 1a and 1b.

The above mentioned light absorbing materials can be used as a single material or as a mixed material in which these materials are mixed. For example, unnecessary light within a wide wavelength region can be absorbed by using a plurality of light absorbing materials which can absorb different wavelengths of light.

A contained amount of the light absorbing material is not limited as long as light not absorbed into the resist of one surface of the transparent substrate layers 1, 1a and 1b does not reach the resist of the other surface. However, the amount is preferably 0.01 to 20% by weight based on the resin of the transparent substrate layers 1, 1a and 1b. When the amount is less than the lower limit, unnecessary light cannot be sufficiently absorbed, which is not favorable. When the amount is more than the upper limit, transparency of the transparent substrate layers 1, 1a and 1b becomes poor, which is not a favorable appearance.

As a material included in the transparent substrate layers 1, 1a and 1b, well-known various additives or stabilizers, for example, an antistat, a plasticizer, a lubricant and an easily adhesive material can be used other than the above mentioned materials. In order to improve adhesiveness to each layer, a corona treatment, a low-temperature plasma treatment, an ion bombardment treatment or a chemical treatment can be carried out as preprocessing.

The resin layers 5a and 5b used in the present invention are arranged in order so that the transparent conductive laminate 11 may have mechanical strength. The resin used for the resin layer is not particularly limited. However, a resin having transparency, adequate hardness and mechanical strength is preferably used. In particular, a light curable resin such as a monomer or a cross linking oligomer of which a main component is acrylate having three or more functions in which a three dimensional cross linkage can be expected is preferably used.

As an acrylate monomer having three or more functions, trimethylolpropane triacrylate, isocyanuric acid EO modified triacrylate, pentaerythritol triacrylate, dipentaerythritol triacrylate, dipentaerythritol tetraacrylate, dipentaerythritol pentaacrylate, dipentaerythritol hexaacrylate, ditrimethylol propane tetraacrylate, pentaerythritol tetraacrylate, polyester acrylate or the like is preferably used. In particular, isocyanuric acid EO modified triacrylate or polyester acrylate are more preferably used. These materials can be used alone or two or more kinds thereof can be combined. In addition to the acrylate having three or more functions, acrylic resins such as epoxy acrylate, urethane acrylate and polyol acrylate can also be combined.

As across linking oligomer, acrylic oligomer such as polyester(meta)acrylate, polyether(meta)acrylate, polyurethane(meta)acrylate, epoxy(meta)acrylate or silicon(meta)acrylate is preferably used. In particular, polyethylene glycol di(meta)acrylate, polypropyleneglycol di(meta)acrylate, bisphenol A type epoxy acrylate, polyurethane diacrylate, cresylic novolak type epoxy(meta)acrylate can be exemplified.

The resin layers 5a and 5b can include an additive such as a particle or a photopolymerization initiator in addition to the above.

An organic or an inorganic particle can be exemplified as the particle which can be added. However, the organic particle is preferably used considering transparency. A particle comprised of an acrylic resin, a polystyrene resin, a polyester resin, a polyolefin resin, a polyamide resin, a polycarbonate resin, a polyurethane resin, a silicon resin, fluorine resin or the like can be exemplified as the organic particle.

An average particle diameter of the particle differs in accordance with the thickness of the resin layers 5a and 5b. However, the lower limit is preferably at least 2 μm, and more preferably at least 5 μm, and the upper limit is preferably at most 30 μm and more preferably at most 15 μm for the reason of appearance such as haze. The contained amount of the particle is preferably at least 0.5 wt % and at most 5 wt % based on the resin.

In the case when a photopolymerization initiator is added, benzoin such as benzoin, benzoin methyl ether, benzoin ethyl ether, benzoin isopropyl ether or benzyl methyl ketal, an alkyl ether type thereof, an acetophenone type such as acetophenone, 2,2-dimethoxy-2-phenylacetophenone or 1-hydroxy-cyclohexyl-phenyl-ketone, on anthraquinone type such as methylanthraquinone, 2-ethylanthraquinone or 2-amyl anthraquinone, a thioxanthone type such as thioxanthone, 2,4-diethylthioxanthone or 2,4-di-isopropylthioxanthon, a ketal type such as acetophenone dimethyl ketal, benzyl dimethyl ketal, a benzophenone type such as benzophenone or 4,4-bismethylaminobenzophenone and an azo compound can be exemplified as a photopolymerization initiator of a radical generation type. These materials can be used alone or a mixed material of two or more kinds thereof can also be used. Furthermore, a combined material of these materials and a photoinitiated auxiliary agent such as tertiary amine such as triethanolamine or methyldiethanolamine or a benzoic acid derivative such as 2-dimethylaminoethyl benzoic acid or 4-dimethylamino benzoic acid ethyl can be used.

An additive amount of the above mentioned photopolymerization initiator is at least 0.1 wt % and at most 5 wt % and preferably at least 0.5 wt % and at most 3 wt % based on the resin of the main component. If the additive amount is less than the lower limit, hardening of a hard coat layer is not sufficient, which is not favorable. In addition, when the additive amount is more than the upper limit, a hard coat layer may turn yellow and weather resistance may decrease, which is not favorable. An ultraviolet ray, an electron ray or a gamma ray can be exemplified as light used for hardening a photo-curable resin. When an electron ray or a gamma ray is used, a photopolymerization initiator or a photoinitiated auxiliary agent is not necessarily added. As an optical source thereof, a high pressure mercury lamp, a xenon lamp, a metal halide lamp, an accelerated electron or the like can be used.

In addition, a thickness of the resin layers 5a and 5b is not limited. However, the thickness is preferably in the range of at least 0.5 μm and at most 15 μm. Furthermore, the refraction index of the resin layer is preferably the same as or similar to that of the transparent substrate layer 11 and the refraction index is preferably about at least 1.45 and at most 1.75.

In a method for forming the resin layers 5a and 5b, a resin or the like being the main component is dissolved in a solvent and formed by a heretofore known coating method such as a die coater, a curtain flow coater, a roll coater, a reverse roll coater, a gravure coater, a knife coater, a bar coater, a spin coater and a micro gravure coater.

The solvent is not particularly limited as long as the above mentioned resin or the like being the main component can be dissolved in the solvent. In particular, ethanol, isopropyl alcohol, isobutyl alcohol, benzene, toluene, xylene, acetone, methyl ethyl ketone, methyl isobutyl ketone, ethyl acetate, n-butyl acetate, isoamyl acetate, ethyl lactate, methyl cellosolve, ethyl cellosolve, butyl cellosolve, methylcellosolve acetate, propylene glycol monomethylether acetate or the like can be exemplified as the solvent. One kind of these solvents can be used alone or two or more kinds thereof can be combined.

The resin layers 5a and 5b of the present invention preferably absorb light for exposing a resist, particularly, ultraviolet light for the same reason as the transparent substrate layers 1, 1a and 1b. A resin layer including an ultraviolet absorbing agent, a resin layer including a resin which has an ultraviolet absorbing function can be exemplified as the resin layer absorbing ultraviolet light. The same material as the material included in the transparent substrate layers 1, 1a and 1b can be exemplified as a particular light absorbing material. In addition, the contained amount of the light absorbing material is also preferably nearly the same as the contained amount included in the transparent substrate layers 1, 1a and 1b.

The resin layers 5a and 5b alone can have a function of absorbing light. Further, the resin layer can have a function of absorbing light with the transparent substrate layers 1, 1a and 1b. Since both of the resin layers and 5b and the transparent substrate layers 1, 1a and 1b have a function of absorbing light, the light which is not absorbed by a resist of one surface of the transparent substrate layer can be sufficiently absorbed, and an overlapping of a pattern on one surface and a pattern on the other surface can be further prevented.

Moreover, both of the resin layers 5a and 5b and the transparent substrate layers 1, 1a and 1b can have a function of absorbing light and a wavelength absorbed by the resin layers 5a and 5b can be different from that absorbed by the transparent substrate layers 1, 1a and 1b. Consequently, it becomes possible that unnecessary light is absorbed in a broad wavelength range, when an optical source having the broad wavelength range is used.

The adhesive layer 6 of the present invention is a layer for bonding the first transparent substrate 1a and the second transparent substrate 1b. An acrylic resin, a silicon series resin and a rubber resin can be exemplified as a resin used for the adhesive layer 6. A resin having excellent cushioning characteristics and transparency is preferably used.

The adhesive layer 6 of the present invention preferably absorbs light for exposing a resist, particularly, ultraviolet light for the same reason as the transparent substrate layers 1, 1a and 1b. A resin layer including an ultraviolet absorbing agent, a resin layer including a resin which has an ultraviolet absorbing function can be exemplified as a resin layer absorbing ultraviolet light. The same material included in the transparent substrate layers 1, 1a and 1b can be exemplified as a particular light absorbing material. In addition, the contained amount of the light absorbing material is also preferably nearly the same as the contained amount in the transparent substrate layers 1, 1a and 1b.

The adhesive layer 6 alone can have a function of absorbing light. In addition, the adhesive layer can have a function of absorbing light with the transparent substrate layers 1, 1a and 1b or the resin layers 5a and 5b. Since the adhesive layer has a function of absorbing light with the transparent substrate layers 1, 1a and 1b or the resin layers 5a and 5b, the light which is not absorbed by a resist of one surface of the transparent substrate layer can be sufficiently absorbed, and an overlapping of a pattern on one surface and a pattern on the other surface can be further prevented.

Moreover, all of the adhesive layer 6, the transparent substrate layers 1, 1a and 1b and the resin layers 5a and 5b can have a function of absorbing light. In addition, the wavelength absorbed by the adhesive layer 6, the transparent substrate layers 1, 1a and 1b and the resin layers 5a and 5b can be varied. Consequently, it becomes possible that unnecessary light is absorbed in a broad wavelength range when an optical source having a broad wavelength range is used.

The optical adjustment layers 2a and 2b are layers for improving visibility and have a function of making patterns formed on the first transparent conductive layer 3a and the second transparent conductive layer 3b less noticeable. When an inorganic compound is used as the optical adjustment layers 2a and 2b, a material such as oxide, sulfide, fluoride or nitride can be used. A refraction index of a thin film made of the inorganic material above differs depending on the material. By forming the thin film having a different refraction index with a predetermined thickness, an optical property can be adjusted. In addition, a plurality of layers can be formed as the layers of the optical adjustment layer in accordance with a desired optical property.

Magnesia oxide (1.6), silicon dioxide (1.5), magnesium fluoride (1.4), calcium fluoride (1.3-1.4), cerium fluoride (1.6), aluminum fluoride (1.3) or the like can be exemplified as a material of a low refraction index. In addition, titanium oxide (2.4), zirconium oxide (2.4), zinc sulfide (2.3), tantalum oxide (2.1), zinc oxide (2.1) indium oxide (2.0), niobium oxide (2.3) and tantalum oxide (2.2) can be exemplified as a material of a high refraction index. The values in parentheses above show the refraction index.

Any one of indium oxide, zinc oxide and tin oxide, a mixed oxide of two or three kinds thereof or a material in which another additive is added to the above mentioned oxide can be exemplified as a material for the first transparent conductive layer 3a and the second transparent conductive layer 3b. However, the material is not particularly limited, since various kinds of materials can be used in accordance with the purpose and application use. At present, the most reliable material having many proven results is indium tin oxide (ITO).

When indium tin oxide (ITO) which is the most common transparent conductive layer is used as the first transparent conductive layer 3a and the second transparent conductive layer 3b, a content ratio of tin oxide doped in indium oxide is arbitrarily selected depending on the specification required in a device. For example, when the transparent substrate is a plastic film, sputtering target material used to crystallize a thin film for the purpose of increasing mechanical strength preferably has the content ratio of tin oxide of less than 10 wt %, in addition the content ratio of tin oxide is preferably at least 10 wt % in order to provide the thin film amorphous with flexibility. Further, when the thin film is required to have low-value resistance, the content ratio of tin oxide is preferably in the range of 3 to 20 wt %.

As a method for manufacturing the optical adjustment layers 2a and 2b, the first transparent conductive layer 3a and the second transparent conductive layer 3b, any film-formation method may be used as long as the film thickness can be controlled. However, a dry process of forming the thin film is superior among the various methods. Physical vapor deposition such as a vacuum evaporation method or sputtering or chemical vapor deposition such as CVD method can be used as the dry process. In particular, sputtering is preferably used in order to form the thin film having a uniform film characteristic in a large area, because the process is stable and the thin film is densified.

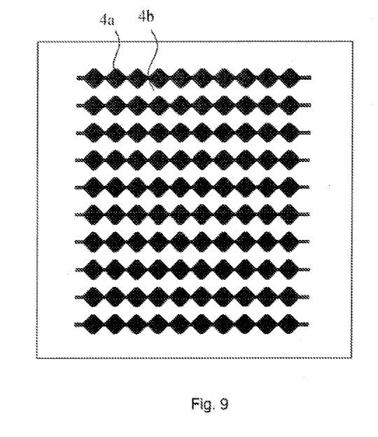

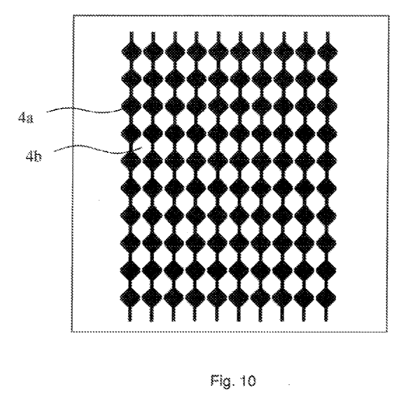

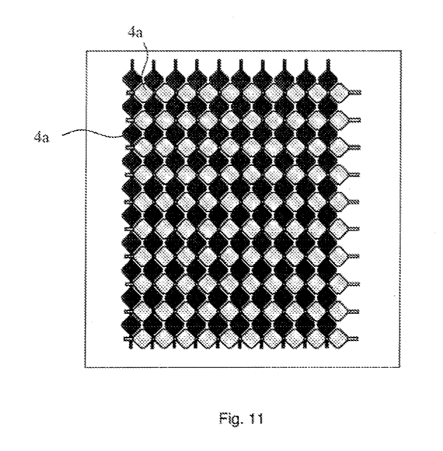

As shown in FIG. 9 and FIG. 10, a pattern of an X coordinate and a pattern of a Y coordinate are provided to the first transparent conductive layer 3a and the second transparent conductive layer 3b. The pattern to be formed includes a conductive pattern area 4a represented by a black color and a nonconductive pattern area 4b represented by a white color, as shown in FIGS. 9 and 10. Further, the conductive pattern area 4a is connected to a circuit which can detect a current change, while it is not illustrated. When a person's finger or the like moves closer to the conductive pattern area 4a which is a sensing electrode, electrical current flows in the circuit, because the entire electrical capacity changes, and thus, a contact location can be detected. The patterns shown in FIGS. 9 and 10 are respectively arranged on both surfaces of the transparent substrate layer. The X coordinate and the Y coordinate are combined as shown in FIG. 11 and connected to the current change sensing circuit. Thus, two-dimensional location information can be obtained. In addition, in FIG. 11, a pattern represented by a black color is the conductive pattern area 4a formed on the upper side of the transparent substrate layer and the pattern represented by a gray color is the conductive pattern area 4a formed on the under side of the transparent substrate layer.

The shape of the patterns of the first transparent conductive layer 3a and the second transparent conductive layer 3b can be a mesh-type pattern or the like as well as a diamond-type pattern as in FIGS. 9 and 10. In order to correctly read two-dimensional location information, the pattern is formed as fine as possible, and it is necessary to accurately carry out position adjustments of the patterns formed on both surfaces of the transparent substrate layer.

As a method for forming the patterns of the first transparent conductive layer 3a and the second transparent conductive layer 3b, photolithography in which resists are applied to the first transparent conductive layer 3a and the second transparent conductive layer 3b and after patterns are formed by exposing and developing, the transparent conductive layer is chemically dissolved, a method in which vaporization is performed by a chemical reaction in a vacuum condition and a method in which the transparent conductive layer is sublimed by a laser can be exemplified. A pattern formation method can be arbitrarily selected in accordance with a pattern shape, accuracy or the like. However, photolithography is preferably used in order to simultaneously form the patterns which are different from each other on the first transparent conductive layer 3a and the second transparent conductive layer 3b.

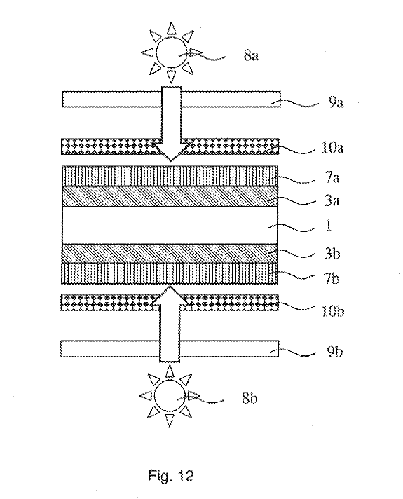

An exposure process by photolithography for the transparent conductive laminate of the present invention is shown in FIG. 12 using the transparent conductive laminate 11 of FIG. 1 as an example. In a method for forming the conductive pattern area 4a and the nonconductive pattern area 4b arranged on the first transparent conductive layer 3a and the second transparent conductive layer 3b of the transparent conductive laminate 11, first, a resist 7a is applied to a surface of the first transparent conductive layer 3a and a resist 7b is applied to a surface of the second transparent conductive layer 3b. Next, an optical source 8a for forming a pattern on the first transparent conductive layer 3a, an optical filter 9a for cutting light having a predetermined wavelength and a mask 10a are respectively arranged in this order from the side of the optical source 8a. An optical source 8b for forming a pattern on the second transparent conductive layer 3b, an optical filter 9b for cutting light having a predetermined wavelength and a mask 10b are respectively arranged in this order from the side of the optical source 8b. Thereafter, the resists 7a and 7b are exposed to the light which has been cut from the light having the predetermined wavelength by the optical filters 9a and 9b.

At this time, the transparent substrate layer 1 can absorb the light which is not absorbed by the resist 7a, because the transparent substrate layer 1 has a function of absorbing light. Therefore, exposure of the resist 7b applied to the surface of the second transparent conductive layer 3b can be prevented. Conversely, the transparent substrate layer 1 can absorb the light which is not absorbed by the resist 7b, and therefore, exposure of the resist 7a applied to the surface of the first transparent conductive layer 3a can be prevented.

In addition, in an exposure process by photolithography for the transparent conductive laminate of the present invention, the patterns can be simultaneously formed on both surfaces of the transparent substrate layer 1. Therefore, the position adjustments of the patterns formed on both surfaces can be easily carried out. When the patterns on both surfaces of the transparent substrate layer 1 are respectively formed on each surface, the position adjustment becomes difficult, because after a pattern is formed on one surface, another pattern is required to be formed on the other surface in accordance with the position of the other pattern. In particular, when a fine pattern is formed in order to correctly read two-dimensional location information or to improve visibility of the patterns, the position adjustment cannot be accurately carried out if the patterns are respectively formed on each surface.

Here, the optical filters 9a and 9b are the filters for cutting light having a predetermined wavelength emitted from the optical sources 8a and 8b. The combination of the optical filters and the transparent substrate layers 1, 1a and 1b which absorb the light for exposing the resist, the resin layers 5a and 5b or the adhesive layer 6 can selectively shield the light for exposing the resist on one surface of the transparent substrate layer and prevent the resist on the other surface from being exposed.

For example, if the transparent substrate layers 1, 1a and 1b, the resin layers 5a and 5b or the adhesive layer 6 have an ultraviolet absorbing agent, the optical filters 9a and 9b shield the light having the wavelength of the visible region and thus, the resist on one surface of the transparent substrate layer is exposed by the light having the wavelength of the ultraviolet region. The light which is not absorbed by the resist on one surface of the transparent substrate layer is absorbed by the ultraviolet absorbing agent included in the transparent substrate layers 1, 1a and 1b, the resin layers 5a and 5b or the adhesive layer 6. Thus, exposure of the resist on the other surface can be prevented.

In this case, the optical filters 9a and 9b preferably have light transmittance of at least 80% for the light having the wavelength of 365 nm. The resist on one surface of the transparent substrate layer only can be exposed by the light having the wavelength of the ultraviolet region by limiting the scope above. Therefore, the resist on the other surface is not exposed and a reflection of the patterns can be prevented. Moreover, some resist depending on a kind of the resist may not sufficiently be exposed by the light which the optical filters transmit. Therefore, by adjusting the light transmittance of the optical filters 9a and 9b for the wavelength of 400 nm from 0.1 to 30%, the resist on one surface is able to be sufficiently exposed. Thus, the resist on the other surface is not exposed and a reflection of the patterns can be prevented.

Moreover, the masks 10a and 10b are the masks for forming the patterns of the resists 7a and 7b. In particular, the masks are used for forming patterns shown in FIGS. 9 and 10 or the like.

The transparent conductive laminate of the present invention shown in FIGS. 2-8 is also able to have the conductive pattern area 4a and the non-conductive pattern area 4b on the first transparent conducive layer 3a and the second transparent conductive layer 3b by the above exposure process.

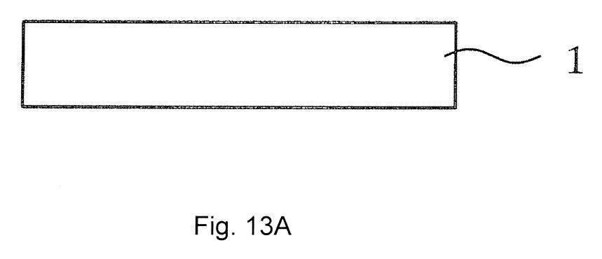

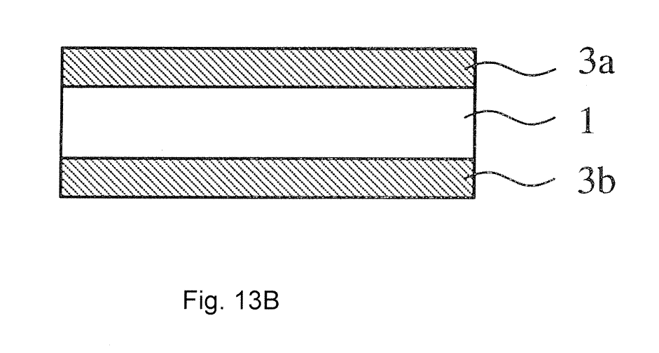

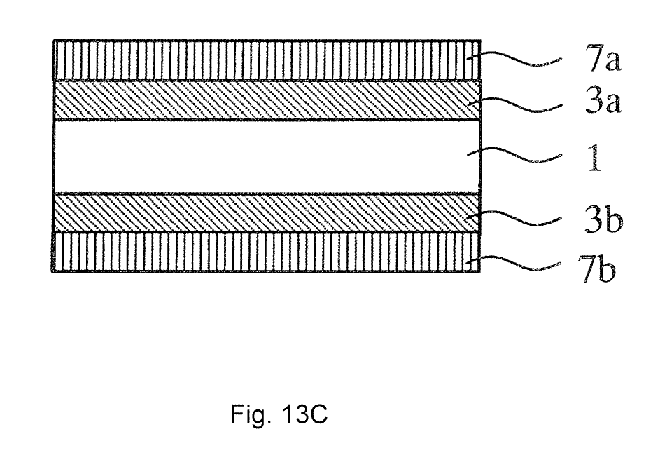

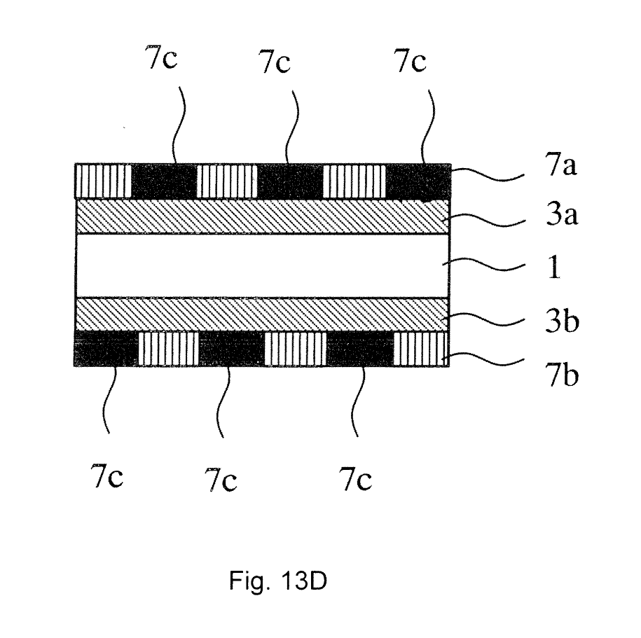

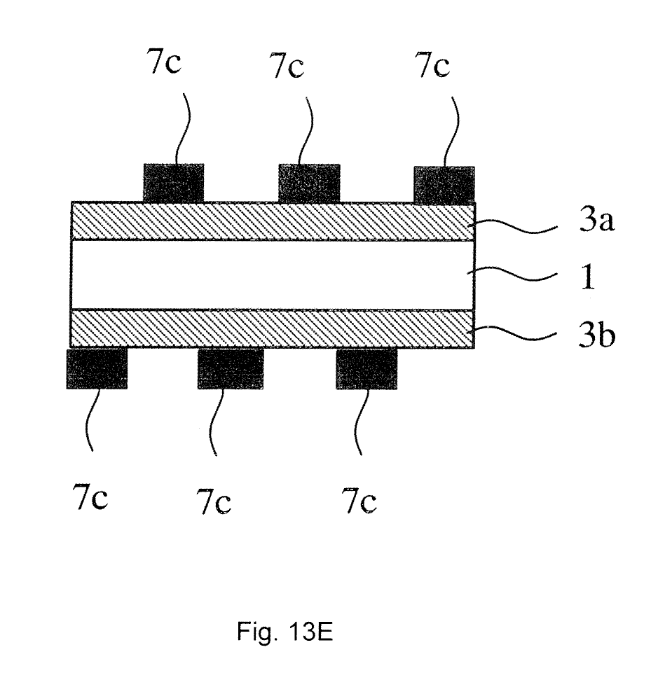

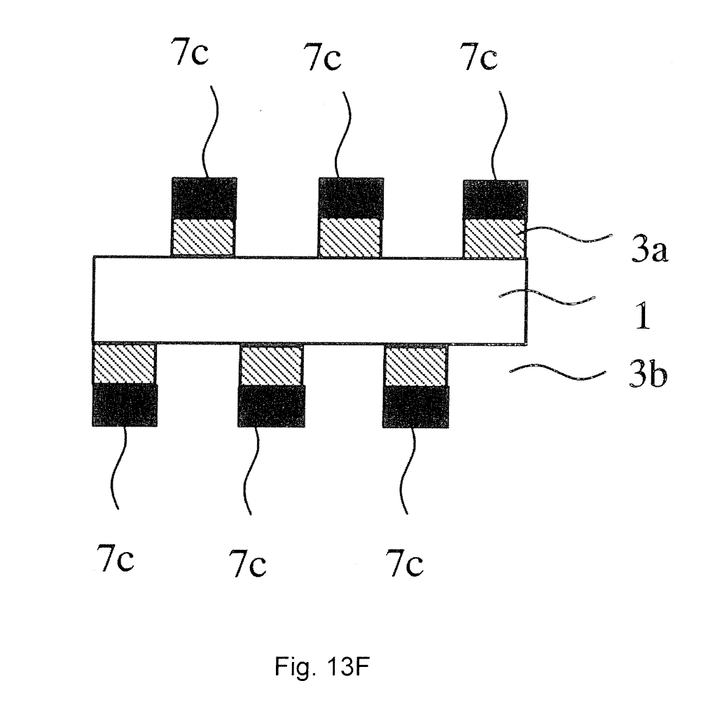

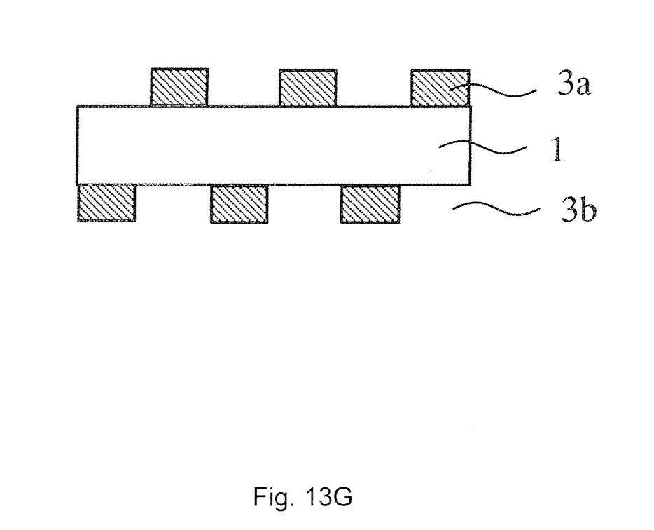

Each process of the pattern formation method by photolithography for the transparent conductive laminate of the present invention is shown in FIGS. 13A-G. FIGS. 13A-G shows each process for manufacturing the transparent conductive laminate 11 of FIG. 1 as an example. Firstly, the transparent substrate 1 is prepared (Process FIG. 13A), and the first transparent conductive layer 3a and the second transparent conductive layer 3b are formed on both surfaces thereof (Process FIG. 13B). Secondly, the resists 7a and 7b are respectively applied to surfaces of the first transparent conductive layer 3a and the second transparent conductive layer 3b (Process FIG. 13C). Thereafter, the resists 7a and 7b are exposed using the optical sources 8a and 8b, the optical filters 9a and 9b for cutting a predetermined wavelength and the masks 10a and 10b shown in FIG. 12 (Process FIG. 13D). In addition, 7c identifies the resist exposed by the light. Next, the unexposed resist is removed by a developing solution (Process FIG. 13E), and the exposed part of the first transparent conductive layer 3a and the second transparent conductive layer 3b is etched (Process FIG. 13F). Lastly, the exposed resist is detached, and thus, the transparent conductive laminate 11 can be obtained (FIG. 13G).

FIGS. 13A-G shows each process of the method for forming the pattern using a negative type resist. However, a pattern can be formed by using a positive type resist.

The transparent conductive laminate of the present invention shown in FIG. 2-8 can also be formed with the conductive pattern area 4a and the nonconductive pattern area 4b of the first transparent conducive layer 3a and the second transparent conductive layer 3b by the each of the above processes.

Moreover, for the transparent conductive laminate 11 of the present invention, a roll to roll method is preferably used from the process for forming the transparent conductive layer on the transparent substrate to the process for detaching the above cited resist. In this way, manufacturing time can be significantly reduced.

The transparent conductive laminate 11 of the present invention preferably has light transmittance of at least 60% for the wavelength of 400 nm and light transmittance of at most 20% for the wavelength of 365 nm. The different patterns can be simultaneously exposed on both surfaces of the transparent conductive laminate when the light transmittance is in the above range. In addition, the position adjustment of the patterns can be easily carried out and the fine patterns can be formed by simultaneously performing exposure on both surfaces. Therefore, when the transparent conductive laminate 11 of the present invention is used as an electrode material of the capacitive type touch panel, two-dimensional location information can be correctly read with excellent sensitivity. Moreover, because the patterns are fine the shape of the patterns cannot be easily seen. Thus, visibility of the patterns is improved.

In particular, the transparent substrate layers 1, 1a and 1b, the resin layers 5a and 5b and the adhesive layer 6 which constitute the transparent conductive laminate 11 preferably have the light transmittance of at least 80% for the wavelength of 400 nm and the light transmittance of at most 20% for the wavelength of 365 nm.

In addition, in the transparent conductive laminate 11 of the present invention, the gap between the entire light transmittance of the conductive pattern area and the nonconductive pattern area is preferably at most 1.5% and the gap between a transmission hue b* of the conductive pattern area and the nonconductive pattern area is preferably at most 2.0. When the gaps are in this range, the shapes of the pattern become less prominent and visibility is improved even when the different patterns are formed on both surfaces of the transparent conductive laminate.

Moreover, a thermal shrinkage rate of the transparent conductive laminate 11 of the present invention at 150 degrees Celsius for 30 minutes is preferably at most 0.5%. When the thermal shrinkage rate is in this range, shrinkage by the heat provided during the process for forming the first transparent conductive layer 3a and the second transparent conductive layer 1b and the process for drying the resists 7a and 7b can be controlled. Therefore, a position gap of the patterns formed on the first transparent conductive layer 3a and the second transparent conductive layer 3b can be prevented.

According to the present invention, a reflection of each pattern can be prevented even when different patterns are simultaneously formed on both surfaces of a transparent conductive layer formed on both surfaces of a transparent substrate layer, since the transparent conductive layer, a resin layer and an adhesive layer are layers which absorb light. In addition, position adjustment can be easily carried out even when a fine pattern is formed, because patterns having different shapes can be simultaneously formed on both surfaces of the transparent substrate layer. Furthermore, the shapes of the patterns can be formed to be less prominent, because fine patterns can be formed on both surfaces of the transparent substrate layer with excellent accuracy. As a result, the transparent conductive laminate having a high visibility can be obtained.

### EXAMPLES

The examples and the comparative examples are explained as follows:

Example 1

A polyethylene terephthalate film (manufactured by Toray, film thickness: 100 μm) having an ultraviolet absorbing function was used as a transparent substrate. A coating liquid for forming a resin layer having the following composition was applied to both surfaces of the transparent substrate by a micro gravure coater. In addition, the coating liquid was dried at 60 degrees Celsius for 1 minute and hardened by an ultraviolet ray, and thus the resin layer was formed.

### [The Composition of the Coating Liquid for Forming the Resin Layer]

| | |
|---|---|
| resin: violet light UV-7605B (manufactured by The | 100 parts by weight |
| Nippon Synthetic Chemical Industry Co., Ltd.) | |
| initiator: Irgacure 184 (manufactured by Ciba Japan) | 4 parts by weight |
| solvent: methyl acetate | 100 parts by weight |

Next, a film of ITO having a thickness of 30 nm was formed as a transparent conductive layer by sputtering on both surfaces of the resin layer formed on both surfaces of the transparent substrate. Thereafter, patterns shown in FIGS. 9 and 10 were simultaneously formed on both surfaces under the following exposure conditions using photolithography as shown in FIGS. 12 and 13, and thus, a transparent pattern area and a nonconductive pattern area were formed on the transparent conductive layer.

### [The Exposure Conditions]

optical source: a super high pressure mercury lamp (manufactured by USHIO INC.)

optical filter: an optical filter which cuts the wavelength having the range of 380 to 600 nm

mask: a mask having a diamond type pattern shown in FIGS. 9 and 10.

### Example 2

A polyethylene terephthalate film (manufactured by Toray, film thickness: 100 μm) not having an ultraviolet absorbing function was used as a transparent substrate. A conductive pattern area and a nonconductive pattern area on a transparent conductive layer were formed using the same condition and method as in Example 1, except that 0.5 parts by weight of a triazine series ultraviolet absorbing agent of (2-[4-[(2-hydroxy-3-tridecyloxypropyl)oxy]-2-hydroxyphenyl]-4,6-bis(2,4-dimethylphenyl)-1,3,5-triazine) was added to a coating liquid for forming a resin layer.

### Comparative Example

A conductive pattern area and a nonconductive pattern area on a transparent conductive layer were formed using the same condition and method as in Example 1, except that a polyethylene terephthalate film (manufactured by Toray, film thickness: 100 μm) not having an ultraviolet absorbing function was used as a transparent substrate.

The obtained transparent conductive laminate was evaluated using the following evaluation method.

### [The Evaluation Method]

Light transmittance: Light transmittance for the wavelength of 100 nm and 365 nm was measured using a spectral photometer (manufactured by Hitachi High-Technologies Corporation), as a transmittance of the obtained transparent conductive laminate.

Apparent condition: The color of the obtained transparent conductive laminate was visually evaluated.

Pattern: Shapes of the patterns on both surfaces of the obtained transparent conductive laminate were visually checked, and whether a pattern shape on one surface was reflected to a pattern shape on the other surface was evaluated.

The obtained transparent conductive laminate obtained in Example 1 had a light transmittance of 61% for 400 nm and 0% for 365 nm. The transparent conductive laminate obtained in Example 2 had a light transmittance of 65% for 400 nm and 10% for 365 nm. Therefore, it was recognized that different patterns on both surfaces of the transparent conductive laminate could be simultaneously exposed. In addition, there was no defect in the apparent condition such as a yellow tinge and no reflection of each pattern on the patterns of both surfaces. On the other hand, the transparent conductive laminate obtained in Comparative Example had a light transmittance of 67% for 400 nm and 40% for 365 nm. Therefore, it was recognized that different patterns on both surfaces of the transparent conductive laminate could not be simultaneously exposed. In addition, while there was no defect in the apparent condition such as a yellow tinge, a reflection of each pattern on the patterns of both surfaces was significantly found.

The present invention can be used for a transparent touch panel attached on an electronic display as an input device. In particular, the present invention can be used for a mobile device or the like which can receive a multi touch.

What is claimed is:

1. A transparent conductive laminate comprising
a transparent substrate layer having a thickness of 10 μm-200 μm;
a first transparent conductive layer formed on a first surface of the transparent substrate layer and a second transparent conductive layer formed on a second surface of the transparent substrate layer;
a first conductive pattern area and a first nonconductive pattern area formed in the first transparent conductive layer;
a second conductive pattern area and a second nonconductive pattern area formed in the second transparent conductive layer;
optionally one or more layers formed between the first transparent conductive layer and the second transparent conductive layer, the optionally one or more layers made of a resin, and the optionally one or more layers having a thickness of 0.5 μm-15 μm,
and
an optical adjustment layer formed between the transparent substrate layer and the first transparent conductive layer and/or between the transparent substrate layer and the second transparent conductive layer, the optical adjustment layer made of an inorganic compound,
wherein
at least one of the transparent substrate layer and the optionally one or more layers includes
first ultraviolet absorbing agent
or
a resin in which a second ultraviolet absorbing agent is copolymerized, the second ultraviolet absorbing agent includes at least one functional group selected from the group consisting of a vinyl group, an acryloyl group, a methacryloyl group, an alcoholic hydroxyl group, an amino group, a carboxyl group, an epoxide group and an isocyanate group,
and
wherein the transparent conductive laminate exhibits a light transmittance for a wavelength of 400 nm equal to or more than 60% and a light transmittance for a wavelength of 365 nm is equal to or less than 20%.

2. The transparent conductive laminate according to claim 1, wherein a gap between an entire light transmittance of the first conductive pattern area and an entire light transmittance of the first nonconductive pattern area is at most 1.5% and a gap between a transmission hue b* of the first conductive pattern area and a transmission hue b* of the first nonconductive pattern area is at most 2.0,
and
wherein a gap between an entire light transmittance of the second conductive pattern area and an entire light transmittance of the second nonconductive pattern area is at most 1.5% and a gap between a transmission hue b* of the second conductive pattern area and a transmission hue b* of the second nonconductive pattern area is at most 2.0.

3. The transparent conductive laminate according to claim 2, wherein the transparent conductive laminate exhibits a thermal shrinkage rate at 150 degrees Celsius for 30 minutes of at most 0.5%.

4. A capacitive touch panel using the transparent conductive laminate according to claim 3 as an electrode material.

5. A transparent conductive laminate comprising:
a transparent substrate layer;
a first transparent conductive layer formed on a first surface of the transparent substrate layer and a second transparent conductive layer formed on a second surface of the transparent substrate layer;
a first conductive pattern area and a first nonconductive pattern area formed in the first transparent conductive layer;
a second conductive pattern area and a second nonconductive pattern area formed in the second transparent conductive layer;
optionally one or more layers formed between the first transparent conductive layer and the second transparent conductive layer;
and
an optical adjustment layer formed between the transparent substrate layer and the first transparent conductive layer and/or between the transparent substrate layer and the second transparent conductive layer, the optical adjustment layer made of an inorganic compound,
wherein
at least one of the transparent substrate layer and the optionally one or more layers includes
a resin in which a ultraviolet absorbing agent is copolymerized, the ultraviolet absorbing agent includes at least one functional group selected from the group consisting of a vinyl group, an acryloyl group, a methacryloyl group, an alcoholic hydroxyl group, an amino group, a carboxyl group, an epoxide group and an isocyanate group,
and
wherein the transparent conductive laminate exhibits a light transmittance for a wavelength of 400 nm equal to or more than 60% and a light transmittance for a wavelength of 365 nm is equal to or less than 20%.
